(19) United States
(12) Patent Application Publication
(10) Pub. No.: US 2026/0328829 A1
(43) Pub. Date: Oct. 22, 2026

(54) Directional Fault Locating in a Power Network

(71) Applicant: Zaphiro Technologies SA, Renens (CH)

(72) Inventors: Lorenzo Zanni, Renens (CH); Mayank Nagendran, Lausanne (CH); Paolo Romano, Lausanne (CH)

(21) Appl. No.: 19/491,496

(22) PCT Filed: Jun. 9, 2023
(86) PCT No.: PCT/EP2023/065544

§ 371 Date: Dec. 9, 2025

(51) Int. Cl. G01R 31/08; H02J 3/0012

(52) U.S. Cl. CPC G01R 31/086; H02J 3/0012

(57) ABSTRACT

A fault location determining arrangement in a power network determines the availability of measurement collecting units in the power network, uses a division of the power network into different areas corresponding to the determined availability, which areas are bounded by measurement points from which the available measurement collecting units collect current measurements, and performs for each area a determining of a sum of currents of the borders to the area, a comparing of the sum with an adaptive current threshold and a determining that there is a fault in the area if the sum exceeds the threshold.

### TECHNICAL FIELD

The present disclosure relates to a method, fault location determining arrangement, computer program and computer program product for determining the location of a fault in a power network as well as to a power network comprising such a fault location determining arrangement.

### BACKGROUND

The determination of fault locations is an important aspect in power networks, such as in medium voltage power distribution networks. This allows an area where the fault occurs to be disconnected for protective measures.

It may be of interest to use differential fault protection where sums of current entering a protected zone are compared with currents leaving the protected zone. One differential fault protection system is disclosed in U.S. Pat. No. 8,884,467. This document also discloses the compensation of the measured current by a compensation value, which compensation value is based on topology information about power cables and their usage.

There may exist a number of measurement collecting units, such as phasor measurement units (PMUs) in a power network. These may have an influence on the way a fault location is determined using differential fault protection, i.e. using differential fault locating. There is therefore a need for providing differential fault locating where the measurement collecting units are considered.

### SUMMARY

One objective is therefore to provide a fault location determination which considers measurement collecting units that are used to collect current measurements.

This objective is achieved by a method for determining the location of a fault in a power network, the power network comprising a number of measurement points, a number of network nodes and a number of measurement collecting units, each being provided in a different network node and being associated with at least one measurement point at the network node, the method being performed in a fault location determining function implemented by a fault location determining arrangement and comprising:
determining the availability of measurement collecting units in the power network,
using a division of the power network into different areas corresponding to the determined availability, which areas are bounded by measurement points from which the available measurement collecting units collect current measurements, and
performing for each area
   determining a sum of currents of the borders to the area,
   comparing the sum with an adaptive current threshold, and
   determining that there is a fault in the area if the sum exceeds the threshold.

The objective is also achieved through a fault location determining arrangement for determining the location of a fault in a power network comprising a number of measurement points, a number of network nodes and a number of measurement collecting units, each being provided in a different network node and being associated with at least one measurement point at the network node, the fault location determining arrangement comprising one or more processors operative to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
   determining a sum of currents of the borders to the area,
   comparing the sum with an adaptive current threshold, and
   determining that there is a fault in the area if the sum exceeds the threshold.

The objective is also achieved through a computer program for determining the location of a fault in a power network, the power network comprising a number of measurement points, a number of network nodes and a number of measurement collecting units, each being provided in a different network node and being associated with at least one measurement point at the network node, the computer program comprising computer program code which when run by one or more processors of a fault location determining arrangement causes the fault location determining arrangement to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
   determining a sum of currents of the borders to the area,
   comparing the sum with an adaptive current threshold, and
   determining that there is a fault in the area if the sum exceeds the threshold.

The objective is also achieved by a computer program product for determining the location of a fault in a power network, the computer program product comprising one or more computer readable storage media with computer program code according to the third aspect.

The objective is also achieved by a power network comprising a fault location determining arrangement, a number of measurement points, a number of network nodes and a number of measurement collecting units, each being provided in a different network node and being associated with at least one measurement point at the network node, the fault location determining arrangement comprising one or more processors operative to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
   determining a sum of currents of the borders to the area,
   comparing the sum with an adaptive current threshold, and
   determining that there is a fault in the area if the sum exceeds the threshold.

The fault location determining function may be implemented by a single processor at a single location in or for the power network, such as via a single fault location determining device. The fault location determining arrangement may thus comprise a fault location determining device with the processor that is operative to implement the fault location determining function. Alternatively, the fault location determining function may be implemented using a number of processors, for instance in one or more of the measurement collecting units, which processors together form the fault location determining arrangement. The measurement collecting units may then also use peer-to-peer communication.

The power network may be a power distribution network. The power distribution network may be a utility distribution network or an industrial distribution network. Additionally, the power distribution network may be a medium voltage, MV, power distribution network. It may additionally be an alternating current, AC, power network. The power network may furthermore be a three-phase power network. In this case the current measurements may be phase current measurements.

Each measurement collecting unit may be provided in a different node. Alternatively, it is possible that at least one node comprises more than one measurement collecting unit.

The measurement collecting units may be connected to current measurement units sensing currents at the measurement points. The measurement points at which current measurements are made may thus be connected to current measurement units, such as current transformers or Rogowski coils.

The measurement collecting units may be phasor measurement units, PMUs, that collect and time-stamp current and possibly also voltage phasors.

The currents that are being summed may have been measured at the same point in time. When the measurement collecting units are PMUs, the summed currents may have the same time stamps. The sum of currents may then also be a sum of currents at a present point in time.

The obtaining of the current measurements may additionally be synchronized.

The power network may have a number of topologies and the division of the power distribution network into different areas may correspond to a present topology of the power network. The power network may comprise a number of switches used to interconnect network elements. In this case a present or currently used topology may depend on the states of theses switches, such as if they are closed or open.

The adaptative current threshold may have or be based on a first contribution. The first contribution may in turn be based on a measurement error that depends on uncertainties of the current measurement units connected to the measurement points that bound the area. The measurement error may be based on a sum of products, which is a sum of currents measured at the boundaries times the uncertainty of the current measurement units used for the measurements.

The first contribution may additionally or instead comprise a pre-fault current that is based on one or more sums of currents at one or more previous points in time.

Furthermore, there may be more than one sum of currents at more than one previous point in time in a time interval preceding the present point in time. In this case the pre-fault current may comprise a statistical or mathematical operation of the sums of currents of the time interval. The time interval may be more than one period long. It may for instance be up to four hundred periods long. The operation may comprise selecting a maximum or minimum sum of currents in the time interval. Alternatively, the operation may comprise forming a mean or average value of the sums of currents in the time interval.

The first contribution may additionally be a combination of the measurement error and the pre-fault current, such as a sum of, a product of, a difference between or a division between the measurement error and the pre-fault current. In this case it is additionally possible that the combination of the measurement error and the pre-fault current, the measurement error and/or the pre-fault current are adjusted.

The adaptative current threshold may also have or be based on a second contribution that is based on electrical parameters of equipment inside the area. The electrical parameters may be current ratings. The equipment may comprise equipment in the group of transformers, generators and motors.

The current threshold may be set as a combination of the first and the second contribution. The combination may be a sum of the first and second contribution. Alternatively, the combination may involve a selection of the first or the second contribution, whichever is highest.

The power network may also comprise a number of current transmission elements in the group of lines, feeders and buses. At least some and with advantage all of the measurement points may be measurement points on current transmission elements. Furthermore, at least two of the measurement points may be measurement points on two different current transmission elements.

The areas may comprise areas of a first type, each bordering at least one node with a measurement collecting unit. The areas of the first type may be bounded by measurement points associated with nodes with measurement collecting units. The areas of the first type may each comprise at least one current transmission element. Furthermore, a node with a measurement collecting unit may also be considered to be an area of a second type.

Generally, all terms used in the claims are to be interpreted according to their ordinary meaning in the technical field, unless explicitly defined otherwise herein. All references to “a/an/the element, apparatus, component, means, step, etc.,” are to be interpreted openly as referring to at least one instance of the element, apparatus, component, means, step, etc., unless explicitly stated otherwise. The steps of any method disclosed herein do not have to be performed in the exact order disclosed, unless explicitly stated.

### BRIEF DESCRIPTION OF THE DRAWINGS

Aspects and embodiments are now described, by way of example, with reference to the accompanying drawings, in which:

FIG. 1 is a diagram schematically illustrating a first type of power network with a number of measurement collecting units used to divide the network into areas;

FIG. 2 is a diagram schematically illustrating a second type of power network with a number of measurement collecting units used to divide the network into areas;

FIG. 3 is a diagram schematically illustrating a current measurement unit connected between a first measurement collecting unit and a first measurement point of a first current transmission element in the power network of the first type;

FIG. 4 schematically shows a realization of a fault location determining device used in the power network;

FIG. 5 schematically shows a computer readable storage medium with computer program code used to implement a fault location determining function of the fault location determining device;

FIG. 6 shows a flow chart of a first number of steps in a method of determining a fault location;

FIG. 7 shows a flow chart of a second number of steps in the method of determining a fault location;

FIG. 8 is a diagram schematically illustrating the second type of power network when one measurement collecting unit is unavailable, and

FIG. 9 is a diagram schematically illustrating the first type of power network when six measurement collecting devices are unavailable.

### DETAILED DESCRIPTION

The aspects of the present disclosure will now be described more fully hereinafter with reference to the accompanying drawings, in which certain embodiments of the invention are shown.

These aspects may, however, be embodied in many different forms and should not be construed as limiting; rather, these embodiments are provided by way of example so that this disclosure will be thorough and complete, and to fully convey the scope of all aspects of invention to those skilled in the art. Like numbers refer to like elements throughout the description.

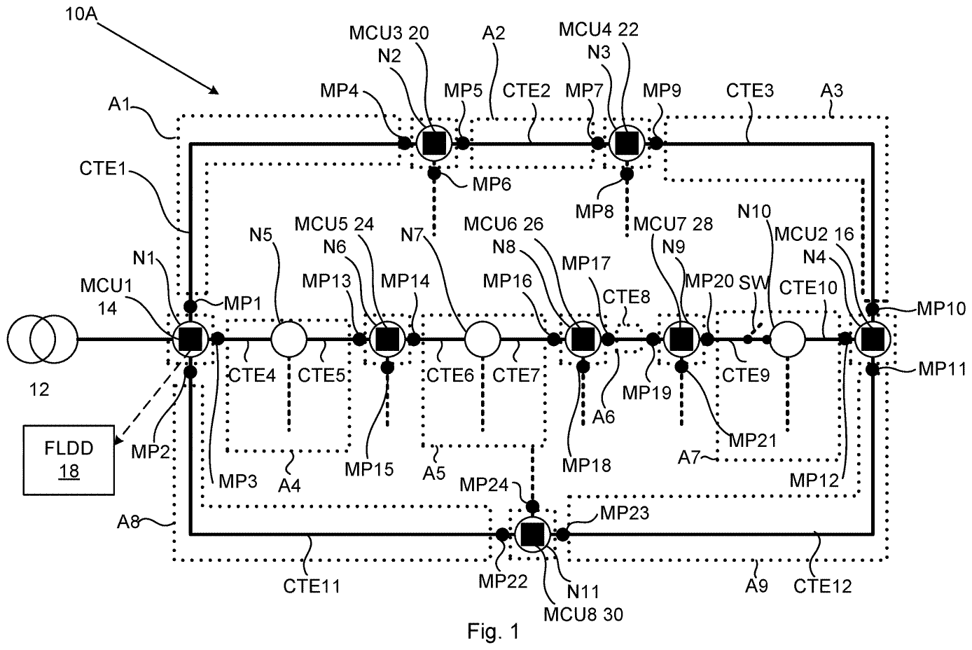

FIG. 1 shows a first type of power network 10A comprising a number of measurement collecting units, which number in this case is eight. In this example the power network is a meshed power distribution network. The power network may be a utility distribution network or an industrial distribution network. In this case, the power network may also be a medium voltage, MV, power distribution network. Furthermore, the power network is also an alternating current, AC, power network, which may additionally be a three-phase power network. The power network may additionally comprise isolated or compensated neutral grounding, for instance using isolating transformers with neutrals connected to ground, either directly or via Petersen coils.

As an example, the network 10A comprises a transformer 12. The transformer 12 has a primary side that may be connected to a power transmission network (not shown). The transformer 12 also has a secondary side connected to a first node N1, which first node N1 is in turn connected to a first end of a first current transmission element CTE1. A second node N2 is in turn connected to a second end Of the first current transmission element CTE1 as well as to a first end of a second current transmission element CTE2. A third node N3 is connected to a second end of the second current transmission element CTE2 as well as to a first end of a third current transmission element CTE3. A fourth node N4 is in turn connected to a second end of the third current transmission element CTE3. Thereby a first branch is formed between the first and the fourth nodes N1 and N4.

The first node N1 is also connected to a first end of a fourth current transmission element CTE4, while a fifth node N5 is connected to a second end of the fourth current transmission element CTE4 as well as to a first end of a fifth current transmission element CTE5. A sixth node N6 is connected to a second end of the fifth current transmission element CTE5 as well as to a first end of a sixth current transmission element CTE6. A seventh node N7 is connected to a second end of the sixth current transmission element CTE6 as well as to a first end of a seventh current transmission element CTE7. An eighth node N8 is connected to a second end of the seventh current transmission element CTE7 as well as to a first end of an eighth current transmission element CTE8. A ninth node N9 is connected to a second end of the eighth current transmission element CTE8 as well as to a first end of a ninth current transmission element CTE9. A tenth node N10 is connected to a second end of the ninth current transmission element CTE9 via a switch SW as well as to a first end of a tenth current transmission element CTE10. The fourth node N4 is in turn connected to a second end of the tenth current transmission element CTE10. Thereby a second branch is formed between the first and the fourth nodes N1 and N4.

The first node N1 is also connected to a first end of an eleventh current transmission element CTE11. An eleventh node N11 is connected to a second end Of the eleventh current transmission element CTE11 as well as to a first end of a twelfth current transmission element CTE12. The fourth node N4 is in this case also connected to a second end of the twelfth current transmission element CTE12. Thereby a third branch is formed between the first and the fourth nodes N1 and N4.

The current transmission elements may be of a variety of types. They may be busbars, feeders or power lines, such as overhead or underground power lines.

The nodes may provide isolation of the current transmission elements from each other and may therefore comprise isolating transformers, which may be three-phase transformers with neutrals connected to ground according to a grounding scheme, which grounding scheme may be a direct connection to ground or a connection to ground via a Petersen coil. The power network may thus comprise a number of isolating transformers with neutrals connected to ground according to a grounding scheme, such as a direct grounding or a grounding via Peterson coils. The second, third, fifth, sixth, seventh, eighth, ninth, tenth and eleventh nodes N2, N3, N5, N6, N7, N8, N9, N10 and N11 are also connected to exemplifying overhead sections that may each continue for a number of further nodes. This is indicated with dashed lines.

The current transmission elements and the isolation transformers are examples of network elements in the power network.

Furthermore, there are a number of measurement points in the power network 10A. At least some and with advantage all of the measurement points may be measurement points on current transmission elements. Furthermore, at least two of the measurement points may be measurement points on two different current transmission elements. Thus, the measurement points are provided at the different current transmission elements.

There is a first measurement point MP1 at the first end of the first current transmission element CTE1, a second measurement point MP2 at the first end of the eleventh current transmission element CTE11, a third measurement point MP3 at the first end of the fourth current transmission element CTE4, a fourth measurement point MP4 at the second end of the first current transmission element CTE1, a fifth measurement point MP5 at the first end of the second current transmission element CTE2, a sixth measurement point MP6 at a connection to an overhead section of the second node N2, a seventh measurement point MP7 at the second end of the second current transmission element CTE2, an eighth measurement point MP8 at a connection to an overhead section of the third node N3, a ninth measurement point MP9 at the first end of the third current transmission element CTE3, a tenth measurement point MP10 at the second end of the third current transmission element CTE3, an eleventh measurement point MP11 at the second end of the twelfth current transmission element CTE12, a twelfth measurement point MP12 at the second end of the tenth current transmission element CTE10, a thirteenth measurement point MP13 at the second end of the fifth current transmission element CTE5, a fourteenth measurement point MP14 at the first end of the sixth current transmission element CTE6, a fifteenth measurement point MP15 at a connection to an overhead section of the sixth node N6, a sixteenth measurement point MP16 at the second end of the seventh current transmission element CTE7, a seventeenth measurement point MP17 at the first end of the eighth current transmission element CTE8, an eighteenth measurement point MP18 at a connection to an overhead section of the eighth node N8, a nineteenth measurement point MP19 at the second end of the eighth current transmission element CTE8, a twentieth measurement point MP20 at the first end of the ninth current transmission element CTE9, a twenty-first measurement point MP21 at a connection to an overhead section of the ninth node N9, a twenty-second measurement point MP22 at the second end of the eleventh current transmission element CTE11, a twenty-third measurement point MP23 at the first end of the twelfth current transmission element CTE12 and a twenty-fourth measurement point MP24 at a connection to an overhead section of the eleventh node N11.

Although measurement points have only been described in relation to current transmission elements, it should be realized that measurement points may be provided at other network elements too, such as at different types of transformers.

Current measurement units sensing currents at the measurement points, such as current transformers or Rogowski coils, may be provided in the nodes at the various measurement points. There may also be one or more voltage measurement units in the power network, such as voltage transformers, for measuring voltages at one or more measurement points.

The power network 10A also comprises a first number of measurement collecting units. The measurement collecting units may be placed in nodes of the network. Each measurement collecting unit may be provided in a different node. Alternatively, it is possible that at least one node comprises more than one measurement collecting unit. As was mentioned earlier, the number of measurement collecting units are eight in the present example and these are placed in the first, second, third, fourth, sixth, eighth, ninth and eleventh nodes N1, N2, N3, N4, N6, N8, N9, N11. Thus there is a first measurement collecting unit MCU1 in the first node N1, a second measurement collecting unit MCU2 in the fourth node N4, a third measurement collecting unit MCU3 20 in the second node N2, a fourth measurement collecting unit MCU4 22 in the third node N3, a fifth measurement collecting unit MCU5 24 in the sixth node N6, a sixth measurement collecting unit MCU6 26 in the eighth node N8, a seventh measurement collecting unit MCU7 28 in the ninth node N9 and an eighth measurement collecting unit MCU8 30 in the eleventh node N11. The measurement collecting units 14, 16, 20, 22, 24, 26, 28, 30 may be phasor measurement units (PMUs) that collect and time-stamp current phasors. The PMUs may be synchrophasor units that collect current measurements made by current measurement units at measurement points at the nodes in which they are provided. The measurement collecting units thus collect measurements from associated measurement points. The first measurement collecting unit 14 collects current measurements made at the first, second and third measurement points MP1, M2, MP3, while the second measurement collecting unit 16 collects current measurements made at the tenth, eleventh and twelfth measurement points MP10, MP11, MP12. Additionally, the third measurement collecting unit 20 collects current measurements made at the fourth, fifth and sixth measurement points MP4, MP5, MP6, the fourth measurement collecting unit 22 collects current measurements made at the seventh, eighth and ninth measurement points MP7, MP8, MP9, the fifth measurement collecting unit 24 collects current measurements made at the thirteenth, fourteenth, and fifteenth measurement points MP13, MP14, MP15, the sixth measurement collecting unit 26 collects current measurements made at the sixteenth, seventeenth and eighteenth measurement points MP16, MP17, MP18, the seventh measurement collecting unit 28 collects current measurements made at the nineteenth, twentieth and twenty-first measurement points MP19, MP20, MP21 and the eighth measurement collecting unit 30 collects current measurements made at the twenty-second, twenty-third and twenty-fourth measurement points MP22, MP23, MP24. The measurement collecting units 14, 16, 20, 22, 24, 26, 28, 30 provide the collected measurements to a fault location determining device FLDD 18. In FIG. 1 only the first measurement collecting unit 14 is shown as sending measurements to the fault location determining device 18. However, it should be realized that also the other measurement collecting units 16, 20, 22, 24, 26, 28, 30 send measurements to the fault location determining device 18.

Furthermore, the measurement collecting units are also used to divide the power network into different areas. The areas are bounded by the measurement points from which the measurement collecting units collect current measurements. More particularly, the areas comprise areas of a first type, each bordering at least one measurement collecting unit as well as areas of a second type formed by the nodes comprising the measurement collecting units.

The first current transmission element CTE1 forms a first area A1 of the first type, which first area A1 is bounded by the first and fourth measurement points MP1, MP4 from which the first and third measurement collecting units 14, 20 of the first and second nodes N1, N2 collect current measurements. The second current transmission element CTE2 forms a second area A2 of the first type, which second area A2 is bounded by the fifth and seventh measurement points MP5, MP7 from which the third and fourth measurement collecting units 20, 22 in the second and third nodes N2, N3 collect current measurements. The third current transmission element CTE3 forms a third area A3 of the first type, which third area A3 is bounded by the ninth and tenth measurement points MP9, MP10 from which the fourth and second measurement collecting units 22, 16 in the third and fourth nodes N3, N4 collect current measurements. The fourth and fifth current transmission elements CTE4, CTE5 together with the fifth node N5 form a fourth area A4 of the first type, which fourth area A4 is bounded by the third and thirteenth measurement points MP3, MP13 from which the first and fifth measurement collecting units 14, 24 in the first and sixth nodes N1, N6 collect currents. The sixth and seventh current transmission elements CTE6, CTE7 together with the seventh node N7 form a fifth area A5 of the first type, which fifth area A5 is bounded by the fourteenth and sixteenth measurement points MP14, MP16 from which the fifth and sixth measurement collecting units 24, 26 in the sixth and eighth nodes N6, N8 collect current measurements. The eighth current transmission element CTE8 forms a sixth area A6 of the first type, which sixth area A6 is bounded by the seventeenth and nineteenth measurement points MP17, MP19 from which the sixth and seventh measurement collecting units 26, 28 in the eighth and ninth nodes N8, N9 collect current measurements. The switch SW is closed and thereby the ninth and tenth current transmission element CTE9, CTE10 together with the tenth node N10 form a seventh area A7 of the first type, which seventh area A7 is bounded by the twentieth and twelfth measurement points MP20, MP12 from which the seventh and second measurement collecting units 28, 16 in the ninth and fourth nodes N9, N4 collect current measurements. The eleventh current transmission element CTE11 forms an eighth area A8 of the first type, which eighth area A8 is bounded by the second and twenty-second measurement points MP2, MP22 from which with the first and eighth measurement collecting units 14, 30 in the first and eleventh nodes N1, N11 collect current measurements. Finally, the twelfth current transmission element CTE12 forms a ninth area A9 of the first type, which ninth area A9 is bounded by the twenty-third and eleventh measurement points MP23, MP11 from which the eighth and second measurement collecting units 30, 16 in the eleventh and fourth nodes N11, N4 collect current measurements.

As is stated above, the nodes in which the measurement collecting units are placed can be considered to be areas of the second type. Thus, the first, second, third, fourth, sixth, eighth, ninth and eleventh nodes N1, N2, N3, N4, N6, N8, N9, N11 are also separate areas of the second type, which areas are each bounded by three measurement points from which the measurement collecting units in these nodes collect current measurements. The areas of the first and second types are indicated through dotted lines.

Thereby it can be seen that the power network 10A comprises a number of measurement points, a number of network nodes and a number of measurement collecting units, each being provided in a different network node and being associated with at least one measurement point at the network node. Each measurement collecting unit may be provided in a different node. Alternatively, it is possible that at least one node comprises more than one measurement collecting unit. Furthermore, the measurement collecting units are used to divide the power network into different areas, where the areas comprise areas of a first type comprising at least one current transmission element, where each area of the first type is bounded by at least one measurement collecting unit. More particularly, the areas are bounded by measurement points from which the measurement collecting units collect current measurements. Each node with a measurement collecting unit can additionally provide an area of a second type.

The power network may have a number of topologies and the division of the power distribution network into different areas may also correspond to the topology of the power network. The power network may comprise a number of switches used to interconnect the network elements, the topology that the power network has may then depend on the states of the switches, such as if they are closed or open. This is exemplified by the switch SW. As can be seen above, there is a seventh area A7 when the switch SW is closed. However, in case it is open, which is indicated with a dashed line, then the seventh area A7 would be split into two different areas, an area A7-1 comprising the ninth current transmission element CTE9 and an area A7-2 comprising the tenth node N10 and the tenth current transmission element CTE10.

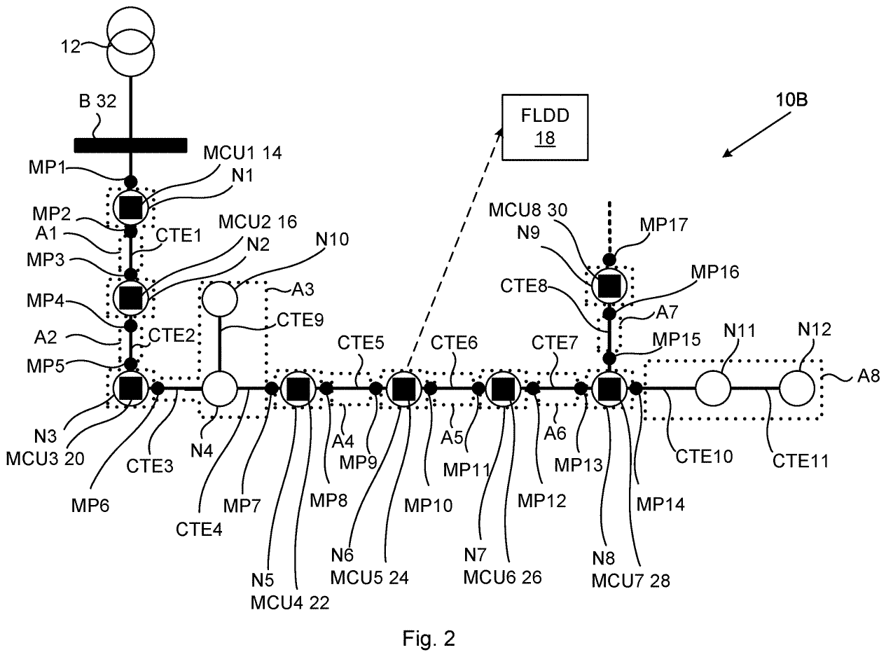

FIG. 2 shows a second type of power network 10B, which is a radial power distribution network. The power distribution network may also here be a utility distribution network or an industrial distribution network. Additionally, the power distribution network may be a medium voltage, MV, power distribution network.

As an example, the network 10B comprises a transformer 12 connected to a busbar B 32, which may be part of a Primary Substation. Furthermore, a feeder is connected to the busbar 32. The feeder has a first node N1 connected between the busbar 32 and a first end of a first current transmission element CTE1. A second node N2 is in turn connected between a second end of the first current transmission element CTE1 and a first end of a second current transmission element CTE2. A third node N3 is connected between a second end of the second current transmission element CTE2 and a first end of a third current transmission element CTE3. A fourth node N4 is connected between a second end of the third current transmission element CTE3, a first end of a fourth current transmission element CTE4 and a first end of ninth current transmission element CTE9. A fifth node N5 is connected between a second end of the fourth current transmission element CTE4 and a first end of a fifth current transmission element CTE5. A sixth node N6 is connected between a second end of the fifth current transmission element CTE5 and a first end of a sixth current transmission element CTE6. A seventh node N7 is connected between a second end of the sixth current transmission element CTE6 and a first end of a seventh current transmission element CTE7. An eight node N8 is connected between a second end of the seventh current transmission element CTE7, a first end of an eight current transmission element CTE8 and a first end of a tenth current transmission element CTE10. A ninth node N9 is connected between a second end of the eight current transmission element CTE8 and a remainder of the feeder leading to a number of further nodes. Furthermore, there is also a tenth node N10 connected to a second end of the ninth current transmission element CTE9, an eleventh node N11 connected between a second end of the tenth current transmission element CTE10 and a first end of an eleventh current transmission element CTE11 as well as a twelfth node N12 connected to a second end of the eleventh current transmission element CTE 11.

The current transmission elements may also here be of a variety of types. They may be busbars, feeders or power lines, such as overhead or underground power lines.

Furthermore, there are a number of measurement points in the power network 10B, which measurement points are provided at the different current transmission elements as well as at the remainder of the feeder connected to the ninth node N9.

There is a first measurement point MP1 at the junction between the first node N1 and the busbar 32, a second measurement point MP2 at the first end of the first current transmission element CTE1, a third measurement point MP3 at the second end of the first current transmission element CTE1, a fourth measurement point MP4 at the first end of the second current transmission element CTE2, a fifth measurement point MP5 at the second end of the second current transmission element CTE2, a sixth measurement point MP6 at the first end of the third current transmission element CTE3, a seventh measurement point MP7 at the second end of the fourth current transmission element CTE4, an eighth measurement point MP8 at the first end of the fifth current transmission element CTE5, a ninth measurement point MP9 at the second end of the fifth current transmission element CTE5, a tenth measurement point MP10 at the first end of the sixth current transmission element CTE6, an eleventh measurement point MP11 at the second end of the sixth current transmission element CTE6, a twelfth measurement point MP12 at the first end of the seventh current transmission element CTE7, a thirteenth measurement point MP13 at the second end of the seventh current transmission element CTE7, a fourteenth measurement point MP14 at the first end of the tenth current transmission element CTE10, a fifteenth measurement point MP15 at the first end of the eighth current transmission element CTE8, a sixteenth measurement point MP16 at the second end of the eighth current transmission element CTE8 and a seventeenth measurement point MP17 at the rest of the feeder at the ninth node N9.

Current measurement units, such as current transformers or Rogowski coils, may be provided at the various measurement points. A voltage measurement unit may also be provided at one of the nodes

In this power network 10B there is second number of measurement collecting units, which second number as an example is also eight. Also, here each measurement collecting unit may be provided in a different node. Alternatively, it is possible that at least one node comprises more than one measurement collecting unit. In the present example, there is a first measurement collecting unit MCU1 14 in the first node N1, a second measurement collecting unit MCU2 16 in the second node N2, a third measurement collecting unit MCU3 20 in the third node N3, a fourth measurement collecting unit MCU4 22 in the fifth node N5, a fifth measurement collecting unit MCU5 24 in the sixth node N6, a sixth measurement collecting unit MCU6 26 in the seventh node N7, a seventh measurement collecting unit MCU7 28 in the eighth node N8 and an eighth measurement collecting unit MCU8 30 in the ninth node N9. Also, these nodes may comprise isolating transformers that employ one of the grounding schemes.

Also, here the measurement collecting units are used to divide the power network into different areas. The first current transmission element CTE1 forms a first area A1 of the first type, which first area A1 is bounded by the second and third measurement points MP2, MP3 from which the first and second measurement collecting units 14, 16 in the first and second nodes N1, N2 collect currents. The second current transmission element CTE2 forms a second area A2 of the first type, which second area A2 is bounded by the fourth and fifth measurement points MP4, MP5 from which the second and third measurement collecting units 16, 20 in the second and third nodes N2, N3 collect current measurements. The third, fourth and ninth current transmission elements CTE3, CTE4, CTE9 and the fourth node N4 form a third area A3 of the first type, which third area A3 is bounded by the sixth and seventh measurement points MP6, MP7 from which the third and fourth measurement collecting units 20, 22 in the third and fifth nodes N3, N5 collect current measurements. The fifth current transmission element CTE5 forms a fourth area A4 of the first type, which fourth area A4 is bounded by eighth and ninth measurement points MP8, MP9 from which the fourth and fifth measurement collecting units 22, 24 in the fifth and sixth nodes N5, N6 collect current measurements. The sixth current transmission element CTE6 forms a fifth area A5 of the first type, which fifth area A5 is bounded by the tenth and eleventh measurement points MP10, MP11 from which the fifth and sixth measurement collecting units 24, 26 in the sixth and seventh nodes N6, N7 collect current measurements. The seventh current transmission element CTE7 forms a sixth area A6 of the first type, which sixth area A6 is bounded by the twelfth and thirteenth measurement points MP12, MP13 from which the sixth and seventh measurement collecting units 26, 28 in the seventh and eighth nodes N7, N8 collect current measurements. The eighth current transmission element CTE8 forms a seventh area A7 of the first type, which seventh area A7 is bounded by the fifteenth and sixteenth measurement points MP15, MP16 from which the seventh and eighth measurement collecting units 28, 30 in the eighth and ninth nodes N8, N9 collect current measurements. Finally, the tenth and eleventh current transmission elements CTE10, CTE11 together with the eleventh and twelfth nodes N11, N12 form an eight area A8 of the first type, which eighth area A8 is bounded by the fourteenth measurement point MP14 from which the seventh measurement collecting unit 28 in the eight node N8 collects current measurements.

Also, the nodes in which the measurement collecting units are placed can be considered to be areas of the second type. Thus, the first, second, third, fifth, sixth, seventh, eighth and ninth nodes N1, N2, N3, N5, N6, N7, N8, N9 may be considered as areas of the second type in the power network, which areas are bounded by the measurement points from which the measurement collecting units in these nodes collect current measurements.

The first measurement collecting unit 14 collects current measurements made at the first and second measurement points MP1, MP2, the second measurement collecting unit 16 collects current measurements made at the third and fourth measurement points MP3, MP4, the third measurement collecting unit 20 collects current measurements made at the fifth and sixth measurement points MP5, MP6, the fourth measurement collecting unit 22 collects current measurements made at the seventh and eighth measurement points MP7, MP8, the fifth measurement collecting unit 24 collects current measurements made at the ninth and tenth measurement points MP9, MP10, the sixth measurement collecting unit 26 collects current measurements made at the eleventh and twelfth measurement points MP11, MP12, the seventh measurement collecting unit 28 collects current measurements made at the thirteenth, fourteenth and fifteenth measurement points MP13, MP14, MP15 and the eighth measurement collecting unit 30 collects current measurements made at the sixteenth and seventeenth measurement points MP16, MP17. In FIG. 2 only the fifth measurement collecting unit 24 is shown as sending measurements to the fault location determining device 18. It should be realized that also here the other measurement collecting units send measurements to the fault location determining device 18.

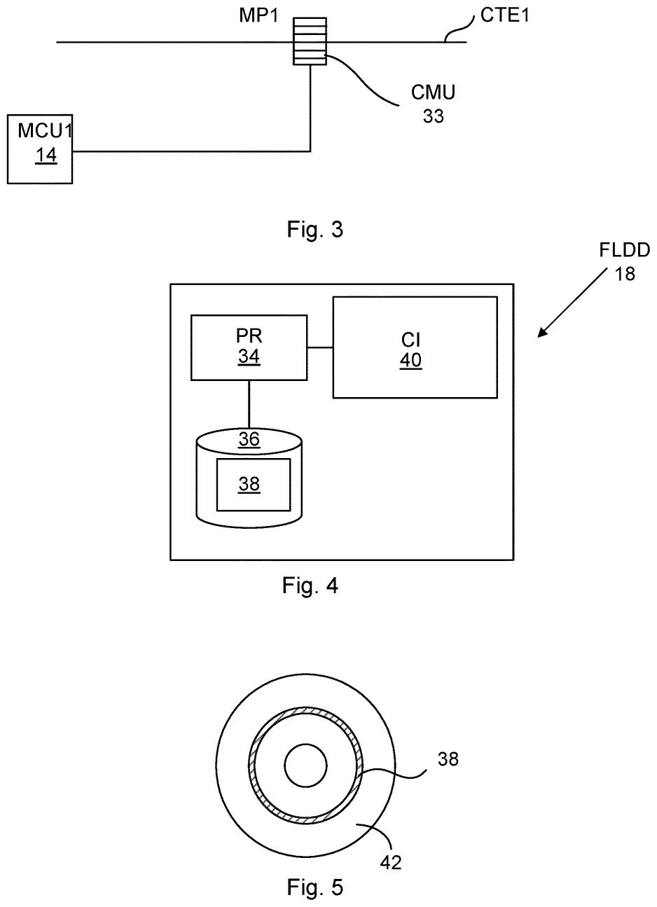

FIG. 3 schematically shows a current measurement unit CMU 33 connected to the first measurement point MP1 of the first current transmission element CTE1 in the first type of power network as well as to the first measurement collecting unit MCU1 14. The measurements from the current measurement unit 33 unit are collected by the first measurement collecting unit 14. It then transfers these collected measurements to the fault location determining device 18. Thereby the first measurement collecting unit 14 is connected to the current measurement unit 33 sensing a current at the first measurement point MP1. The measurement collecting units may all in a similar way be connected to the current measurement units associated with the measurement points from which they collect current measurements.

FIG. 4 schematically shows one realization of the fault location determining device FLDD 18.

The fault location determining device 18 comprises a processor PR 34 and a data storage 36 with computer program instructions or computer program code 38 that, when executed by the processor 34, implements a fault location determining function. There is also a communication interface CI 40. The communication interface 40 may be a wireless interface, an Ethernet interface or even an optical interface for communicating with the measurement collecting units.

The fault location determining device 18 may thus comprise a processor 34 with associated program memory 36 including computer program code 38 for implementing the fault location determining function.

A computer program may also be provided via a computer program product, for instance in the form of one or more computer-readable storage media or data carriers, like CD ROMs or a memory sticks, carrying such a computer program with the computer program code, which will implement the fault location determining function when being loaded into one or more processors. One such computer-readable storage medium in the form of a CD ROM 42 with the above-mentioned computer program code 38 is schematically shown in FIG. 5.

According to aspects of the present disclosure, there is a fault location determining arrangement comprising one or more processors and which fault location determining arrangement performs the fault location determination function with respect to the power network in or for which it is provided. In the examples of FIGS. 1 and 2, the fault location determining arrangement is provided as the fault location determining device 18 comprising a processor performing the fault location determining function. In this example, the fault location determining function may thus be implemented by a single processor of a single fault location determining device at a single location in or for the power network. The fault location determining device may be placed in a central location as indicated in FIGS. 1 and 2 or in one of the nodes, for instance as a part of a measurement collecting unit.

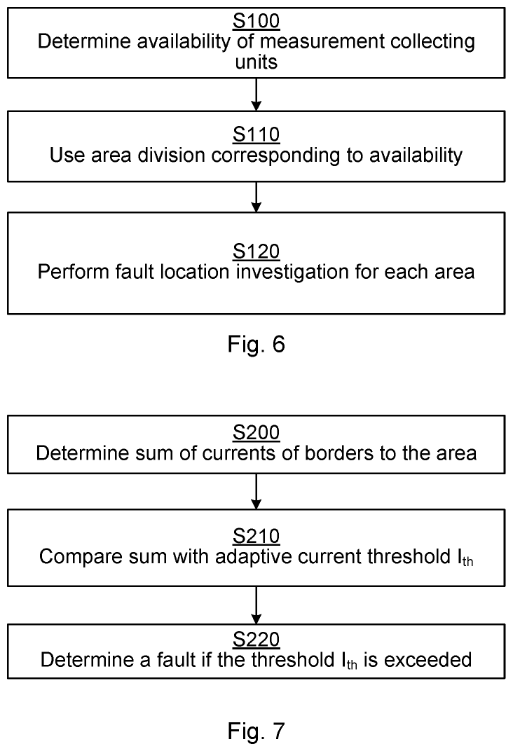

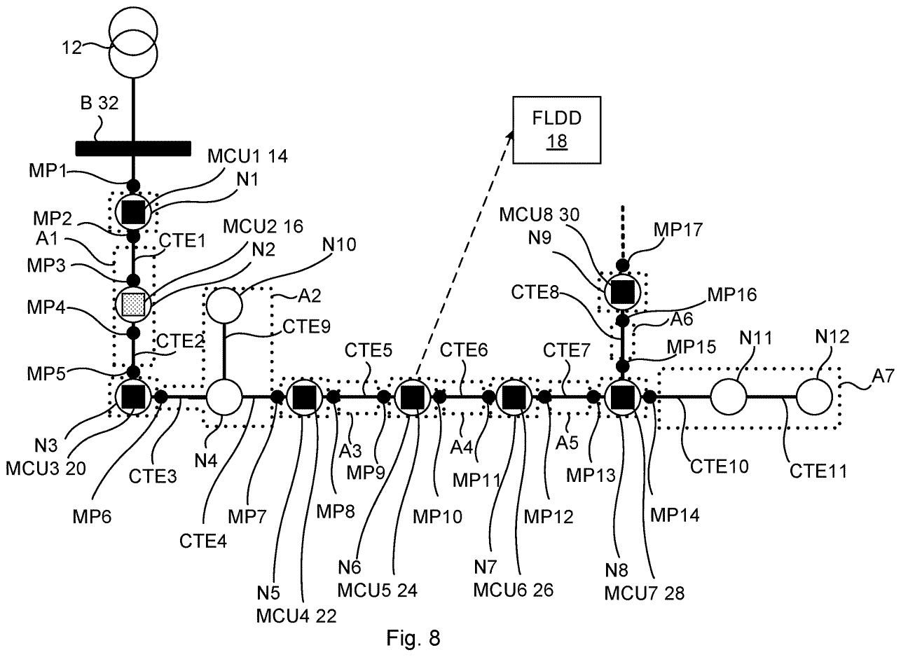

The fault location determining function determines the location of a fault in the power network. How this can be done for the radial power distribution network in FIG. 2, will now be further elaborated with reference also being made to FIGS. 6, 7 and 8, where FIG. 6 shows a flow chart of a first number of steps in a method of determining a fault location, FIG. 7 shows a flow chart of a second number of steps in the method of determining a fault location and FIG. 8 is a diagram schematically illustrating the second type of power network when one measurement collecting device is unavailable.

As can be seen above, the measurement collecting units collect measurements from the measurement points to which they are connected via current measurement units. These measurements are then sent to the fault location determining device. The measurements are typically regularly collected and sent at discrete points in time by the measurement collecting units. Put differently, the fault location determining device receives the regularly collected measurements from the measurement collecting units. The presence or absence of such communication defines the availability of the measurement collecting units. A measurement collecting unit the transmissions of which can be received may then be considered to be available, while a measurement collecting unit for which transmissions cannot be received may be deemed unavailable.

As can be seen above, the measurement points from which the measurement collecting units collect current measurements are used to divide the power network into areas. According to aspects of the present disclosure, this division is dynamic and made based on the availability of the measurement collecting units. There is thus a division of the power network into different areas corresponding to the determined availability. In case the fault location determining device can receive measurements from all measurement collecting units in the power network, then they are all available. Therefore, the division made into areas shown in FIGS. 1 and 2 may be a default division made in case all measurement collecting units are available.

The current measurement units may continuously measure currents at the measurement points and supply them to the measurement collecting units, which in turn regularly provide the current measurements with time stamps and supply the time-stamped current measurements to the fault location determining function. Thereby the measurement collecting units may supply the fault location determining function with current measurements from the measurement points having been collected at a present point in time.

The current measurements may also be synchronized. The fault location determining device 18 may thus receive the current measurements that have the same time stamp simultaneously from all the measurement collecting units. For this reason, it is also possible that the time-synchronization has an accuracy, which may be an accuracy of below 0.1 microseconds.

The operation of the fault location determining arrangement may comprise the fault location determining function determining the availability of the measurement collecting units, S100. The availability may be investigated recurringly, such as according to a cycle, for example at each discrete time instance when measurements are made. The determining of the availability may additionally involve determining which measurement collecting units that send current measurements with a time stamp of the investigation cycle and determining the measurement collecting units from which measurements with the time stamp are received to be available and measurement collecting units from which no measurements with the time stamps are received as being unavailable. A change in availability may also involve an adding of a measurement collecting unit to the power network and/or a relocation of a measurement collecting unit, which added and/or relocated measurement collecting unit sends collected current measurements to the fault location determining arrangement.

The fault location determining function may then use a division of the power network into different areas, which division corresponds to the available measurement collecting units, S110. The division of the power distribution network into different areas may also correspond to a present topology of the power network. It may more particularly depend on the present states of switches used to interconnect the network elements of the power network.

The areas are bounded by measurement points from which the available measurement collecting units collect current measurements. In case the present availability investigation shows that the availability is the same as in a preceding availability investigation, e.g. an investigation made immediately before the present investigation according to the investigation cycle for the same topology, then the preceding division may be used. However, if there is a change in availability and/or topology, then the division into areas is changed. The fault location determining arrangement may have knowledge in advance of how the division into area is, based on which measurement collecting units are available. There may thus exist a mapping between available measurement collecting units and division into areas. Alternatively, the fault location determining function may make a new division into areas when there is a change in availability and/or topology. After having determined which division into areas is to be used, the fault location determining function continues and performs a fault location investigation or determination for each area using the determined division, S120.

What a change may look like can be seen in FIG. 8, in which the second measurement collecting unit 16 in the second node N2 has become unavailable, for instance through stopping sending current measurements. This has redefined the areas, so that the first area A1 is now made up of the first current transmission element CTE1, the second node N2 and the second current transmission element CTE2, which first area A1 is now bounded by the second and fifth measurement points MP2, MP5 from which the available first and third measurement collecting units 14, 20 in the first and third nodes N1, N3 collect current measurements. The third, fourth and ninth current transmission elements CTE3, CTE4, CTE9 and the fourth node N4 form the second area A2 of the first type. The fifth current transmission unit CTE5 forms the third area A3 of the first type, the sixth current transmission element CTE6 forms the fourth area A4 of the first type, the seventh current transmission element CTE7 forms the fifth area A5 of the first type, the eighth current transmission element CTE8 forms the sixth area A6 of the first type and the tenth and eleventh current transmission elements CTE10, CTE11 together with the eleventh and twelfth nodes N11, N12 form the seventh area A7 of the first type. Also, the node in which the second measurement collecting unit 16 is placed is no longer an area of the second type. Thus, the first, third, fifth, sixth, seventh, eighth and ninth nodes N1, N3, N5, N6, N7, N8, N9 are now the remaining areas of the second type.

The fault location determining function thus makes a fault determination with respect to each area. For each area the following operations may be performed:

The fault location determining function determines a sum of currents of the borders to the area, S200, where the currents that are being summed may have been measured at the same point in time. When the measurement collecting units are PMUs, the summed currents may have the same time stamps. The sum of currents may then be a sum of currents at a present point in time. The obtaining of the current measurements may additionally be synchronized.

The sum may be a sum made in respect of a phase. The sum may thus be a sum of currents of a first phase at the borders of the area. In the example of the first area A1 in FIG. 8, the sum may be a sum of the current of the first phase at the second measurement point MP2 and present point in time and the current of the first phase at the fifth measurement point MP5 and present point in time. The sum is then compared with an adaptive current threshold Iₜₕ, S210, and the area is determined to be faulty in case the sum exceeds the adaptive threshold Iₜₕ, S220. The area may more particularly be considered to have a phase-to-ground fault. In case the sum remains below the current threshold Iₜₕ then the phase is considered healthy in the investigated area. This type of investigation is made for each area and each phase. It is also recurringly made according to the investigation cycle.

After an area has been determined to be faulty, the area may then be disconnected for protective measures. In the example of FIG. 8, it is for instance possible that the first end of the first current transmission element CTE1 is connected to the first node N1 via a first circuit breaker and that the second end of the second current transmission element CTE2 is connected to the third node N3 via a second circuit breaker. It is possible that the first and optionally also the second circuit breaker is opened in case of a fault in the first area A1.

As was mentioned above, the threshold is adaptive. It may more particularly have or be based on a first contribution.

The first contribution may depend or be based on a measurement error that in turn is based or depends on uncertainties of the current measurement units connected to the measurement points that bound the area. The measurement error may more particularly be based on a sum of products, where each product is the product of the current measured at one of these measurement points times the uncertainty of the current measurement unit used for the measurement. Thereby the sum of products may be a sum of currents measured at the boundaries times the uncertainty of the current measurement units used for the measurements.

The first contribution may additionally or instead be based on a pre-fault current, which may be based on one or more sums of currents at one or more previous points in time. Such sums of currents are then sums of currents measured at the measurement points that bound the area according to a present division. There may additionally be more than one sum of currents at more than one previous point in time in a time interval preceding the present point in time, such as in a time interval separated a number of time instances from the present time instance, like a time interval separated from the current time instance by one or more periods of the current. The time interval may also be more than one period long, such as up to four hundred periods long. The pre-fault current may comprise or be formed through a statistical or mathematical operation on the sums of currents of the time interval. The operation may comprise selecting a maximum or minimum sum of currents in the time interval. Alternatively, the operation may comprise forming a mean or average value of the sums of currents in the time interval. The pre-fault current may thus as an example be formed as the maximum or minimum sum of currents in the time interval or as the average or mean value of the sums of currents in the time interval.

It is furthermore possible that the first contribution is a combination of the measurement error and the pre-fault current, such as a sum of, a product of, a difference between or a division between the measurement error and the pre-fault current. In this case it is additionally possible that either of the measurement error and the pre-fault current or both is adjusted. Also, the combination may be adjusted.

Furthermore, the adaptive current threshold Iₜₕ may also have or be determined based on a second contribution that in turn is based on electrical parameters of equipment inside the area being investigated. The electrical parameters may be current ratings. The equipment may comprise equipment in the group of transformers, generators and motors.

The current threshold Iₜₕ may be set as a combination of the first and the second contribution. The combination may be a sum of the first and second contribution. Alternatively, the combination may involve a selection of the first or the second contribution, whichever is highest.

The way that the adaptive current threshold Iₜₕ is selected may also be described in the following way:

A fault may be declared for an area if the differential current, i.e. the sum of currents at the borders of the area exceeds the corresponding current threshold. This is done separately on each phase.

The differential current is calculated as the vector sum of all currents on one phase at all the measurement collecting units connected to measurement points that enclose the area.

The current threshold computation may be based on the following values:
1. Measurement error—Every current measurement unit has an associated uncertainty defined as a function of the measured value. The current measurement error may be computed as shown in Equation 1,

$$Meas Error = {\sum }_{n = 1}^{Number of MCUs} {I}_{X}^{n} * {U}_{X}^{n} \qquad ( 1 )$$

where I represents the current measured on a phase X and U is the uncertainty of the current measurement unit for the measured current obtained by interpolation. The computation is done for all phases separately.
2. Pre-fault differential current (I_{pre-fault})—The maximum differential current in a pre-defined window before the current time instant may be used to account for any current mismatches between the measurement collecting units. This allows the boundaries of the area to enclose multiple pieces of equipment which may not always result in the differential current being zero.
3. Equipment Ratings—The adaptive threshold can include a value that is based on the electrical parameters, such as current ratings, of network equipment (e.g transformers, generators or motors) inside the investigated area.

The current threshold Iₜₕ may be given by Equation 2:

Iₜₕ=(k1*(k2*Meas Error+k3*I_{pre-fault}))+k₄ (2)
where k1, k2 and k3 are constants used to scale the first contribution for additional operating margins and k₄ is a value forming the second contribution and which depends on electrical parameters of equipment contained in the area.

The division of the power network into areas based on the availability of measurement collecting units has the advantage of making the fault location determination function robust. Changes to the network topology or the loss of measurement collecting units due to communication issues have a limited impact on the fault location—the fault location automatically adapts to the new network topology and measurement collecting unit availability.

The adaptive nature of the current threshold also has a number of advantages. The computation of the pre-fault differential current as the maximum of the vector sum of the currents at the available measurement collecting units at the boundaries of an area, with the areas being regularly updated, is beneficial because the fault location determining function is allowed to handle areas being redefined—even if the areas expand to include within them several transformers which means that there is some current absorbed/injected in that area. Thereby there are less false alarms, making the fault location determining function more reliable—while at the same time improving the sensitivity—as the threshold is adaptively computed without a fixed high value.

The inclusion of a minimum threshold, which could be based on the rating of a transformer or any distributed generation, allows for sudden increases in the current absorbed or injected without causing false alarms, thereby improving the reliability of the fault-location determining function.

The computation of the measurement error as a sum of all individual sensor errors at the measurement collecting units enclosing an area improves the sensitivity of the fault location determining function by using the actual uncertainty associated with a measured value instead of the worst possible uncertainty as is normally the practice.

Above a change of the second type of power network was discussed. It is possible that also the first type of power network is changed.

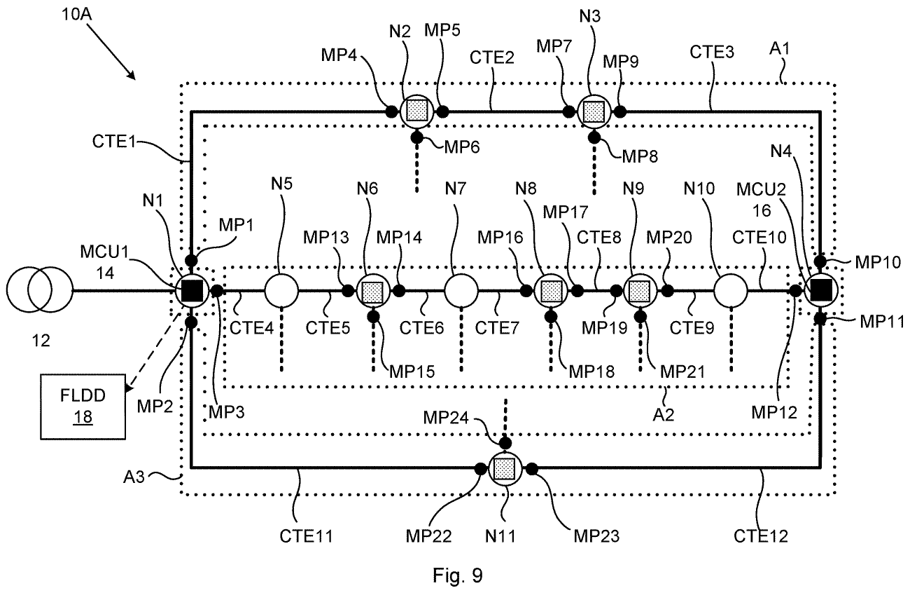

FIG. 9 shows one such change, where the third, fourth, fifth, sixth, seventh and eighth measurement collecting units in the second, third, sixth eighth, ninth and eleventh nodes N2, N3, N6, N8, N9, N11 are unavailable. It can be seen that in this case the first branch between the first and the fourth nodes N1, N4, i.e. the first, second and third current transmission elements CTE1, CTE2, CTE3 and the second and third nodes N2, N3 form the first area A1 of the first type, which first area A1 is bounded by the first and tenth measurement points MP1, MP10 from which the first and second current measurement units 14, 16 in the first and fourth nodes N1, N4 collect current measurements. The second branch with the fourth, fifth, sixth, seventh, eighth, ninth and tenth current transmission elements CTE4, CTE5, CTE6, CTE7, CTE8, CTE9, CTE10 together with the fifth, sixth, seventh, eighth, ninth and tenth nodes N5, N6, N7, N8, N9, N10 form the second area A2 of the first type, which second area A2 is bounded by the third and twelfth measurement points MP3, MP12 from which the first and second measurement collecting units 14, 16 collect current measurements. In a similar manner the third branch between the first and the fourth nodes N1, N4, i.e. the eleventh and twelfth current transmission elements CTE11, CTE12 and the eleventh node N11 form the third area A3 of the first type, which third area A3 thus is bounded by the second and eleventh measurement points MP2, MP11 from which the first and second measurement collecting units 14, 16 collect current measurements.

In the examples above, the areas were bounded by one or two nodes. It should be realized that an area may be bounded by more than two nodes, such as for instance by three or four nodes.

The above-described fault location determining function is a differential fault location determining function. It should be realized that it is possible to combine this differential fault location determining function with a directional fault location determining function.

A directional fault location may be performed in the following way with the power network in FIGS. 2 and 8 as an example:

There may be one voltage measurement unit in the power network, which voltage measurement unit may measure a voltage at a corresponding measurement point of a network node and supply the voltage measurement to a corresponding measurement collecting unit associated with the network node. As an example, a voltage measurement unit may make a voltage measurement at the seventh measurement point MP7 and supply the measurement to the fourth measurement collecting unit 22 of the fifth node N5. The voltage measurement may additionally be a three-phase voltage measurement obtained at the measurement point. The fourth measurement collecting unit 22 may in turn process the voltage measurement, which may involve forming at least one voltage phasor based on the voltage measurement. It may also involve time stamping the voltage phasor. The processed voltage measurement is then provided to the fault location determining function in the fault location determining arrangement.

A plurality of current measurement units may also each measure a current at a corresponding plurality of measurement points and supply the current measurements to corresponding measurement collecting units in network nodes associated with the measurement points. As an example, current measurement units at all of the measurement points MP1-MP17 may make current measurements and supply these to the corresponding measurement collecting units 14, 16, 20, 22, 24, 26, 28, 30 and where the current measurements are made at the same time as the voltage measurement V. Also, the current measurements may be three-phase current measurements obtained at the measurement points. The measurement collecting units 14, 16, 20, 22, 24, 26, 28, 30 may process the current measurements, which may involve forming current phasors based on the current measurements. The processing may also involve time stamping the current phasors. The processed current measurements are then provided by the available measurement collecting units to the fault location determining function in the fault location determining arrangement. The processed current measurements may comprise processed current measurements sent from the fourth measurement collecting unit 22 used for the voltage. However, the processed current measurements also comprise processed current measurements sent from all of the other available measurement collecting units. Thereby the fault location determining device 18 receives processed current measurements from the fourth measurement collecting unit 22 that have been measured at the seventh and eighth measurement points MP7, MP8 as well as processed current measurements that have been collected by the other available measurement collecting units 14, 16, 20, 24, 26, 28, 30 from the other measurement points MP1, MP2, MP3, MP4, MP5, MP6, MP9, MP10, MP11, MP12, MP13, MP14, MP15, MP16, MP17. The processed current measurements are thus received from all of the measurement points to which all of the available measurement collecting units are connected.

The voltage measurement and the current measurements may be synchronized. The fault location determining device 18 may thus receive the processed voltage and current measurements that have the same time stamp simultaneously from all the available measurement collecting units. For this reason, it is also possible that the time-synchronization has the previously mentioned accuracy.

The directional fault location may start with the fault location determining device 18 obtaining a voltage based on the voltage measurement V made at the previously mentioned measurement point MP8. This voltage is based on processing of the voltage measurement V made by the used measurement collecting unit 22, which processing may at least comprise time stamping. The voltage may be a phase voltage, for instance in the form of a phasor supplied by the used measurement collecting unit 22. As an alternative the fault location determining function may perform additional processing such as combining the different phase voltages in order to obtain the voltage as a zero-sequence voltage.

The fault location determining function also obtains a number of currents based on current measurements made at the plurality of measurement points MP1-MP17, which currents are also obtained based on processing of the current measurements made by the available measurement collecting units 14, 16, 20, 22, 24, 26, 28, 30, which processing may at least comprise time stamping. The currents that are obtained may be phase currents supplied by the available measurement collecting units, for instance in the form of phasors. As an alternative additional processing may be performed, such as combining the different phase currents in order to obtain the currents as zero-sequence currents.

Thereafter the fault location determining device 18 continues and investigates if there is a fault and if one fault is determined then also the area in which the fault has occurred is determined. This involves an investigation of the obtained voltage and currents, which as an example are zero-sequence currents and voltages.

The investigation may also optionally involve comparing the obtained voltage with a fixed voltage threshold and declaring or considering the power network to be healthy in case the voltage is below the voltage threshold.

In case the voltage is above the voltage threshold, the investigation continues with comparing each current with a fixed current threshold. There is also a determining of a number of phase angles based on the obtained voltage and all of the obtained currents, where each phase angle is a phase angle between the obtained voltage and a different obtained current. The determining of a number of phase angles may thus be a determining of a number of phase angles between the obtained voltage and the obtained currents. There is thus determined one phase angle for each current being received by the fault location determining device 18. Each current is also compared with the fixed current threshold, which fixed current threshold may be set to a level that indicates the existence of a fault.

The investigation may additionally comprise analysing the threshold comparisons and phase angles, and a determination, based on the analysis, of if a fault has occurred in the power network and if such a fault is deemed to have occurred, the area in which it has occurred. There is thus an analysing, for each obtained current, whether it crosses the fixed current threshold or not and an analysing of the phase angle to the obtained voltage as well as a determining, based on the analysis, if a fault has occurred in the power network and if a fault has occurred also the area in which it has occurred.

There are a number of possible variations that can be made. For instance, the power network is not limited to power distribution networks. The power network may as an example be a power generation network or power transmission network instead. Furthermore, the fault location determining arrangement was above provided as a fault location determining device 18 comprising a processor performing the fault location determining function. This device may be provided anywhere in or for the power network. As an alternative, the fault location determining device may be distributed, such as over one or more of the measurement collecting units. Thereby, the fault location determining function may be implemented using a number of processors, for instance in one or more of the measurement collecting units, which processors together form the fault location determining arrangement. These measurement collecting units may then cooperate to perform the fault location determining function. The measurement collecting units may then also use peer-to-peer communication.

The aspects of the present disclosure have mainly been described above with reference to a few embodiments and examples thereof. However, as is readily appreciated by a person skilled in the art, other embodiments than the ones disclosed above are equally possible within the scope of the invention, as defined by the appended patent claims.

1. A method for determining the location of a fault in a power network, the power network comprising a number of measurement points, a number of network nodes and a number of measurement collecting units, each being provided in a different network node and being associated with at least one measurement point at the network node, the method being performed in a fault location determining function implemented by a fault location determining arrangement and comprising:
determining the availability of measurement collecting units in the power network,
using a division of the power network into different areas corresponding to the determined availability, which areas are bounded by measurement points from which the available measurement collecting units collect current measurements, and
performing for each area
determining a sum of currents of the borders to the area,
comparing the sum with an adaptive current threshold Iₜₕ, and
determining that there is a fault in the area if the sum exceeds the threshold.

2. The method as claimed in claim 1, wherein the measurement collecting units are connected to current measurement units sensing currents at the measurement points.

3. The method as claimed in claim 1, wherein the adaptative current threshold is determined based on a first contribution.

4. The method as claimed in claim 3, wherein the measurement collecting units are connected to current measurement units sensing currents at the measurement points, and wherein the first contribution is based on a measurement error that depends on uncertainties of the current measurement units connected to the measurement points that bound the area.

5. The method as claimed in claim 3, wherein the sum of currents is a sum of currents at a present point in time, and the first contribution comprises a pre-fault current that is based on one or more sums of currents at one or more previous points in time.

6. The method as claimed in claim 5, wherein there is more than one sum of current at more than one previous point in time in a time interval preceding the present point in time and the pre-fault current includes a statistical or mathematical operation of the sums of currents of the time interval.

7. The method as claimed in claim 5, wherein the measurement collecting units are connected to current measurement units sensing currents at the measurements points, wherein the first contribution is based on a measurement error that depends on uncertainties of the current measurement units connected to the measurement points that bound the area, and wherein the first contribution is a combination of the measurement error and the pre-fault current.

8. The method as claimed in claim 1, wherein the current threshold is determined based on a second contribution that is based on electrical parameters of equipment inside the area.

9. The method as claimed in claim 8, wherein the adaptative current threshold is determined based on a first contribution, and wherein the current threshold is selected as a combination of the first and the second contribution.

10. The method according to claim 1, wherein the power network may have a number of topologies and the used division of the power distribution network into different areas corresponds to a present topology of the power network.

11. A fault location determining arrangement for determining the location of a fault in a power network including a number of measurement points, a number of network nodes and a number of measurement collecting units, each being provided in a different network node and being associated with at least one measurement point at the network node, the fault location determining arrangement including one or more processors operative to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
determining a sum of currents of the borders to the area,
comparing the sum with an adaptive current threshold Iₜₕ, and
determining that there is a fault in the area if the sum exceeds the threshold.

12. The fault location determining arrangement as claimed in claim 11, further comprising a fault location determining device with the processor operative to implement the fault location determining function.

13. A computer program for determining the location of a fault in a power network, the power network including a number of measurement points, a number of network nodes and a number of measurement collecting units, each being provided in a different network node and being associated with at least one measurement point at the network node,
the computer program comprising a computer program code which when run by one or more processors of a fault location determining arrangement causes the fault location determining arrangement to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
determining a sum of currents of the borders to the area,
comparing the sum with an adaptive current threshold Iₜₕ, and
determining that there is a fault in the area if the sum exceeds the threshold.

14. A computer program product for determining the location of a fault in a power network, the computer program product comprising one or more computer-readable storage media with computer program code for determining the location of a fault in a power network, the power network comprising a number of measurement points, a number of network nodes and a number of measurement collecting units, each being provided in a different network node and being associated with at least one measurement point at the network node,
the computer program includes a computer program code which when run by one or more processors of a fault location determining arrangement causes the fault location determining arrangement to implement a fault location determining function comprising:
determining the availability of measurement collecting units in the power network,
using a division of the power network into different areas corresponding to the determined availability, which areas are bounded by measurement points from which the available measurement collecting units collect current measurements, and
performing for each area
determining a sum of currents of the borders to the area,
comparing the sum with an adaptive current threshold Iₜₕ, and
determining that there is a fault in the area if the sum exceeds the threshold.

15. A power network comprising a fault location determining arrangement, a number of measurement points, a number of network nodes and a number of measurement collecting units, each being provided in a different network node and being associated with at least one measurement point at the network node, the fault location determining arrangement including one or more processors operative to implement a fault location determining function including:
determining the availability of measurement collecting units in the power network, using a division of the power network into different areas corresponding to the determined availability, which areas are bounded by measurement points from which the available measurement collecting units collect current measurements, and
performing for each area
determining a sum of currents of the borders to the area,
comparing the sum with an adaptive current threshold Iₜₕ, and
determining that there is a fault in the area if the sum exceeds the threshold.

16. The method as claimed in claim 2, wherein the adaptative current threshold is determined based on a first contribution.

17. The method as claimed in claim 2, wherein the current threshold is determined based on a second contribution that is based on electrical parameters of equipment inside the area.

18. The method according to claim 2, wherein the power network may have a number of topologies and the used division of the power distribution network into different areas corresponds to a present topology of the power network.

19. The method as claimed in claim 4, wherein the sum of currents is a sum of currents at a present point in time, and the first contribution comprises a pre-fault current that is based on one or more sums of currents at one or more previous points in time.

20. The method as claimed in claim 6, wherein the measurement collecting units are connected to current measurement units sensing currents at the measurement points, wherein the first contribution is based on a measurement error that depends on uncertainties of the current measurement units connected to the measurement points that bound the area, and wherein the first contribution is a combination of the measurement error and the pre-fault current.
